(19) United States
(12) Patent Application Publication
(10) Pub. No.: US 2006/0118157 A1
(43) Pub. Date: Jun. 8, 2006

(54) Thermoelectric generator and control system

(75) Inventors: Kris W. Johnson, Washington, IL (US); Mahmoud A. Taher, Peoria, IL (US)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Caterpillar Inc

(21) Appl. No.: 11/002,770

(22) Filed: Dec. 3, 2004

(51) Int. Cl. H01L 35/34; H01L 37/00

(52) U.S. Cl. 136/205; 136/201

(57) ABSTRACT

A method is provided for use in a thermoelectric generator control system including a thermoelectric generator, a DC-DC converter, and a controller. The method may include monitoring a voltage output of the thermoelectric generator and determining a voltage change on the voltage output. The method may also include calculating an adjustment for the DC-DC converter in response to the voltage change on the voltage output such that an output voltage from the DC-DC converter remains at a predetermined voltage level. Further, the method may include applying the adjustment to the DC-DC converter.

### TECHNICAL FIELD

This disclosure relates generally to work machine generators, and more particularly to thermoelectric generators and control systems on work machines.

### BACKGROUND

Modem work machines normally need electrical power to operate various components associated with them in response to fuel efficiency concerns and desired performance characteristics. Hybrid work machines have been developed, for example, to rely on a combination of electric energy and energy produced by traditional combustion engines to power certain electrical accessories and traction devices. Traditional combustion engines, such as internal combustion engines and other types of power sources, may generate significant levels of waste heat, and typically, this waste heat is expelled to the atmosphere through an exhaust system. As a result, the energy associated with the waste heat is lost.

Thermoelectric generators have been made to recover at least a portion of the waste heat produced by traditional combustion engines and to convert the recovered energy to electrical power. For example, a thermoelectric generator can be placed in an exhaust stream of a traditional combustion engine. The heat of the exhaust stream can be applied to one side of the thermoelectric material of the thermoelectric generator. If the other side of the thermoelectric material is cooled to maintain a temperature gradient across the thermoelectric material, a voltage potential may be generated by the thermoelectric material and may be used to drive a current through a resistive load. For example, U.S. Pat. No. 5,625,245 issued to Bass on Apr. 29, 1997, describes a 1KW thermoelectric generator placed in the exhaust stream of a diesel engine for an on-highway truck to convert heat from the exhaust into electrical energy. However, such conventional thermoelectric generators often rely on relatively inefficient bulk thermoelectric materials. Conventional thermoelectric generators also lack systematic approaches to address cooling characteristics of an entire work machine.

Methods and systems consistent with certain features of the disclosed systems are directed to solving one or more of the problems set forth above.

### SUMMARY OF THE INVENTION

In one embodiment, a method is provided for use in a thermoelectric generator control system including a thermoelectric generator, a DC-DC converter, and a controller. The method may include monitoring a voltage output of the thermoelectric generator and determining a voltage change on the voltage output. The method may also include calculating an adjustment for the DC-DC converter in response to the voltage change on the voltage output such that an output voltage from the DC-DC converter remains at a predetermined voltage level. Further, the method may include applying the adjustment to the DC-DC converter.

In another embodiment, a thermoelectric generator system is provided for use on a work machine with an engine. The system may include a thermoelectric generator selectively accepting thermal energy from an exhaust stream from the engine to generate a voltage on a generator voltage output. A DC-DC converter may include a voltage input coupled with the generator voltage output of the thermoelectric generator to convert the voltage to a predetermined level on a converter voltage output. The system may also include a controller coupled to both the DC-DC converter and the thermoelectric generator and configured to maintain the predetermined level on the converter voltage output.

### BRIEF DESCRIPTION OF THE DRAWINGS

The accompanying drawings, which are incorporated in and constitute a part of this specification, illustrate several embodiments and together with the description, serve to explain the principles of the disclosed embodiments. In the drawings:

FIG. 1 is a pictorial illustration of an exemplary system that may incorporate certain disclosed embodiments;

FIG. 2 illustrates a block diagram of a power subsystem consistent with certain disclosed embodiments;

FIG. 3A illustrates an exemplary configuration of thermoelectric materials consistent with certain disclosed embodiments;

FIG. 3B illustrates another exemplary configuration of thermoelectric materials consistent with certain disclosed embodiments;

FIG. 3C illustrates another exemplary configuration of thermoelectric materials consistent with certain disclosed embodiments;

FIG. 3D illustrates another exemplary configuration of thermoelectric materials consistent with certain disclosed embodiments;

FIG. 3E illustrates another exemplary configuration of thermoelectric materials consistent with certain disclosed embodiments;

FIG. 3F illustrates another exemplary configuration of thermoelectric materials consistent with certain disclosed embodiments;

FIG. 4 illustrates a block diagram of an exemplary controller in a thermoelectric generator control system;

FIG. 5 illustrates a flowchart of an automatic voltage conversion process performed by the exemplary controller consistent with certain disclosed embodiments;

FIG. 6 illustrates a flowchart of a control process performed by the exemplary controller consistent with certain disclosed embodiments; and

FIG. 7 illustrates a flowchart of a dual-mode operational process performed by the exemplary controller consistent with certain disclosed embodiments.

### DETAILED DESCRIPTION

Reference will now be made in detail to exemplary embodiments, which are illustrated in the accompanying drawings. Wherever possible, the same reference numbers will be used throughout the drawings to refer to the same or like parts.

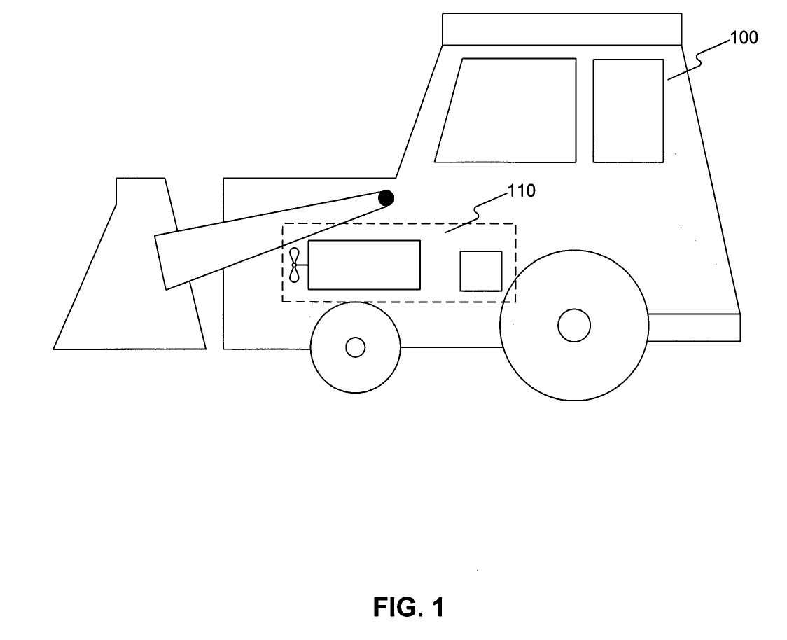

FIG. 1 illustrates an exemplary work machine 100 in which features and principles consistent with certain disclosed embodiments may be incorporated. Work machine 100 may refer to any type of fixed or mobile machine that performs some type of operation associated with a particular industry, such as mining, construction, farming, transportation, etc. and operates between or within work environments (e.g., construction site, mine site, power plants and generators, on-highway applications, etc.). Non-limiting examples of mobile machines include commercial machines, such as trucks, cranes, earth moving vehicles, mining vehicles, backhoes, material handling equipment, farming equipment, marine vessels, aircraft, and any type of movable machine that operates in a work environment. Although, as shown in FIG. 1, work machine 100 is an earth handling type work machine, it is contemplated that work machine 100 may be any type of work machine. Further, work machine 100 may be a conventionally powered, hybrid electric, and/or fuel cell powered work machine, such as an on-highway truck.

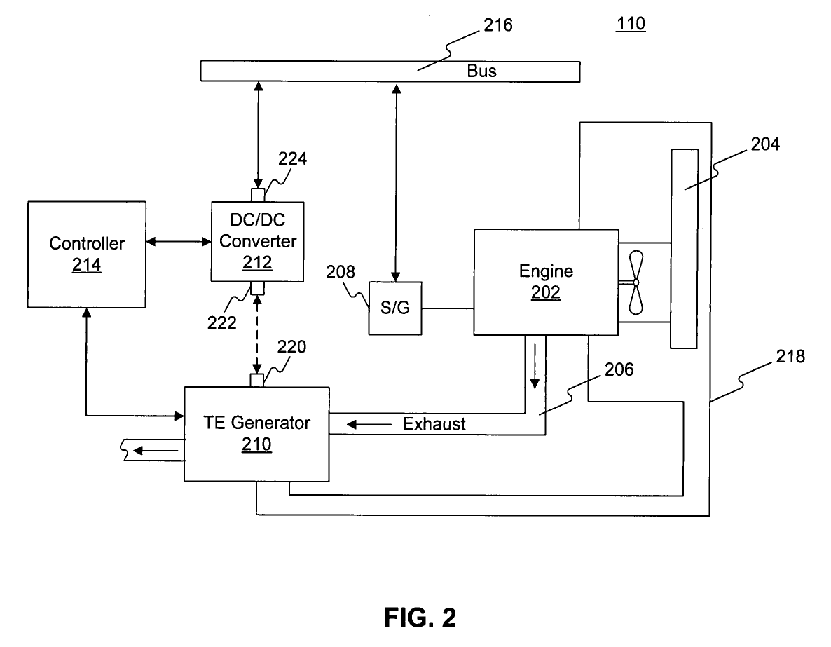

As shown in FIG. 1, work machine 100 may include a power subsystem 110 that generates power and electricity for work machine 100. The details of power subsystem 110 are illustrated in FIG. 2. As shown in FIG. 2, power subsystem 110 may include an engine 202, a radiator 204, an exhaust line 206, a starter generator 208, a thermoelectric generator 210, a DC-DC converter 212, a controller 214, an electric bus 216, and a cooling line 218.

Engine 202 may be any type of engine that generates power for work machine 100 and, as a byproduct, an exhaust stream including waste heat. To cool engine 202, a cooling system including radiator 204 and cooling line 218 may be provided to circulate coolant to cool engine 202. Starter generator 208 may be operatively coupled to engine 202 and may be located within a flywheel housing (not shown) of engine 202. When engine 202 is running, starter generator 208 may operate in a generating mode to provide a source of power to electrical systems (not shown) via electric bus 216. Alternatively, starter generator 208 may be used in a starting mode to crank engine 202. Further, starter generator 208 may also be used in a motoring mode when engine 202 is running to provide mechanical power for the drive line of work machine 100.

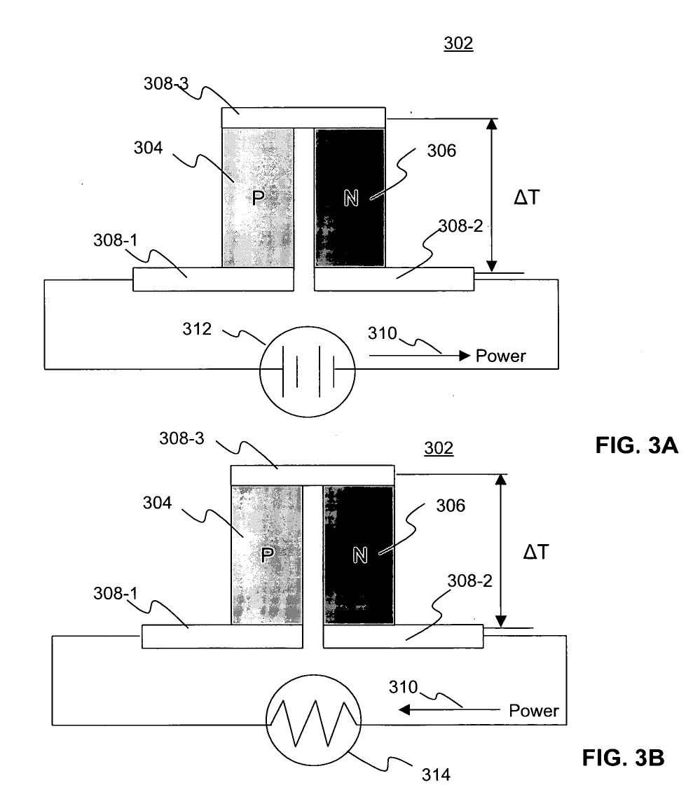

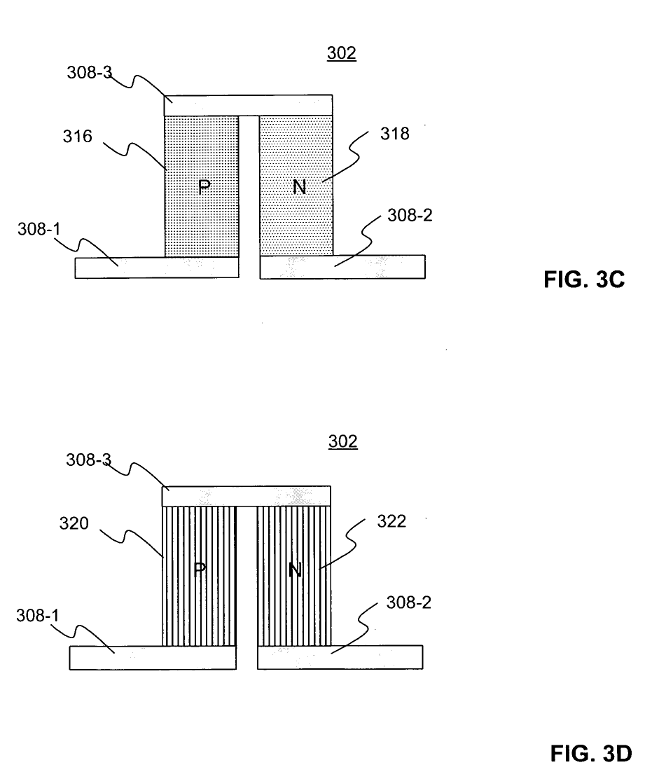

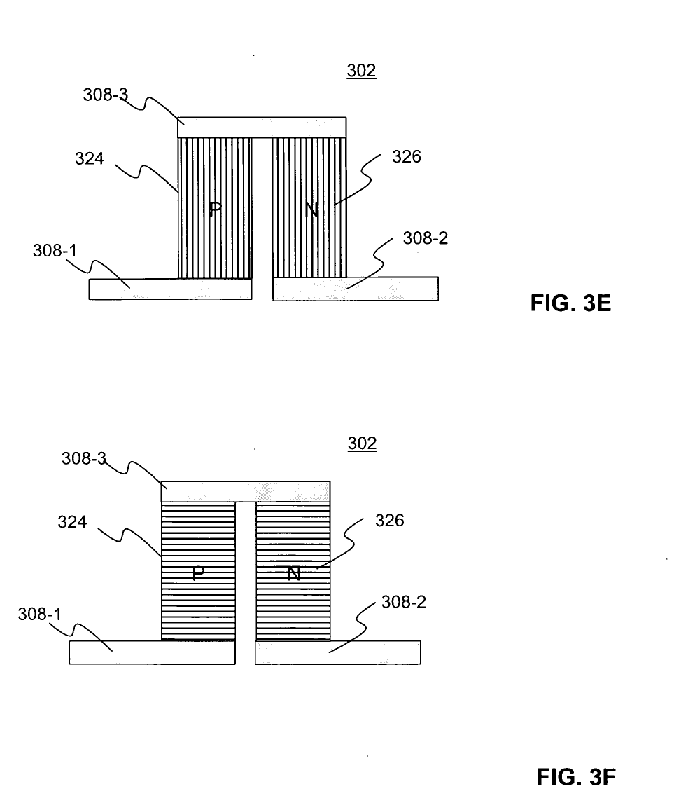

Thermoelectric generator 210 may be provided to recover at least a portion of the energy associated with the waste heat produced by engine 202 using thermoelectric materials. Thermoelectric materials may be operated based on the Seebeck effect or the Peltier effect. FIG. 3A illustrates an exemplary configuration of thermoelectric materials operating based on the Peltier effect. As shown in FIG. 3A, thermoelectric materials may be semiconductors that are packaged in a thermoelectric couple 302. Thermoelectric couple 302 may include a positive-type P element 304 and a negative-type N element 306. Thermoelectric couple 302 may also include junctions 308-1 to 308-3. When an electrical power 310 from a current source 312 is passed through thermoelectric couple 302, a temperature gradient ΔT across junctions 308-1 and 308-2 and junctions 308-3 of thermoelectric couple 302 may be generated. Such phenomenon is known as the Peltier effect. The polarity of the temperature gradient (i.e., which junction or junctions have a high temperature) may be determined by the polarity of current source 312 providing power 310 to thermoelectric couple 302.

Conversely, as shown in FIG. 3B, an electrical power 310 may be generated through an electrical load 314 if a temperature difference ΔT is maintained between the junctions 308-1 and 308-2 and junction 308-3 of thermoelectric couple 302 where a heat source is provided at one junction and a heat sink is provided at the other junctions to maintain the temperature difference ΔT (a phenomenon known as the Seebeck effect).

The effectiveness of a thermoelectric material in converting electrical energy to heating or cooling energy (i.e., coefficient of performance “COP”), or converting heat energy to electrical energy (conversion efficiency “η”) depends on the thermoelectric material's figure of merit termed “Z” and the average operating temperature “T”. Z is a material characteristic that is defined as:

$$Z = \frac{{S}^{2} σ}{λ} ,$$

where S is the Seebeck coefficient of the material, σ is the electrical conductivity of the material, and λ is the thermal conductivity of the material.

Because Z changes as a function of temperature, Z may be reported along with the temperature T, at which the properties are measured. Thus, the dimensionless product ZT may be used instead of Z to reflect the effectiveness of the thermoelectric material. To improve the COP or η of thermoelectric materials, an increase in ZT may be necessary.

From the definition of Z, an independent increase in the Seebeck coefficient and/or electrical conductivity, or an independent decrease in the thermal conductivity may contribute to a higher ZT. Conventional low ZT thermoelectric materials, also known as bulk thermoelectric materials, may have ZT values that do not exceed one (1). New breakthrough thermoelectric materials with low dimensional structures have demonstrated a higher figure of merit ZT, which may be approaching 5. These breakthrough materials include zero-dimensional quantum dots, one-dimensional nano wires, two-dimensional quantum well and superlattice thermoelectric structures.

While bulk thermoelectric materials may be used in thermoelectric generator 210, in certain embodiments, new breakthrough or high ZT thermoelectric materials may also be used. High efficiency thermoelectric materials that may have ZT values between 0.5 and 10 may be provided consistent with disclosed embodiments. In one embodiment, as shown in FIG. 3C, thermoelectric couple 302 may include a P element 316 and an N element 318 that may be made of zero-dimensional quantum dots of lead-tin-selenium-telluride or other thermoelectric materials. In another embodiment, as shown in FIG. 3D, thermoelectric couple 302 may include a P element 320 and an N element 322 that may be made of one-dimensional nano wires of bismuth-antimony or other thermoelectric materials. In another embodiment, as shown in FIG. 3E, thermoelectric couple 302 may include a P element 324 and an N element 326 that may be made of two-dimensional quantum well or superlattice thermoelectric structures of silicon-germanium, boron-carbon or other thermoelectric materials.

As explained above, thermoelectric couple 302 may include thermoelectric materials having low dimensional structures, such as two-dimensional quantum wells. Arrangement of the low dimensional structures relative to the flow of heat may be in-plane, as shown in FIG. 3E. Alternatively, the arrangement of the low dimensional structures relative to the flow of heat may also be cross-plane, as shown in FIG. 3F.

It is understood that the structures and thermoelectric materials in thermoelectric couple 302 are exemplary and not intended to be limiting. Other structures and thermoelectric materials may be included without departing from the principle and scope of disclosed embodiments. For example, in certain embodiments, thermoelectric couple 302 used by thermoelectric generator 210 may include P elements with different structures from N elements. For instance, the P elements may be made of zero-dimensional quantum dots, while the N elements may be made of two-dimensional quantum well or superlattice thermoelectric structures.

Returning to FIG. 2, thermoelectric generator 210 may be coupled with exhaust line 206 to receive a source of heat on one side of the thermoelectric material included in thermoelectric generator 210. Another side of the thermoelectric material may be cooled by cooling line 218 of work machine 100 to maintain a temperature gradient across the thermoelectric material. As a result, a voltage may be generated on an output/input voltage terminal 220 of thermoelectric generator 210. Output/input voltage terminal 220 of thermoelectric generator 210 may be further coupled with an input/output voltage terminal 222 of DC-DC converter 212, such that the voltage generated may be converted to an output voltage on an output/input voltage terminal 224 at a desired level (e.g., 14.4V, 30V, 300V, etc.) by DC-DC converter 212. The output voltage on output/input voltage terminal 224 of DC-DC converter 212 may then be applied on electric bus 216 to be used by other systems (not shown) of work machine 100.

DC-DC converter 212 may be any type of electronic device that accepts a DC input voltage and produces a DC output voltage at the same or different level than the input voltage. DC-DC converter 212 may also regulate the input voltage or isolate noises on the input. Further, DC-DC converter 212 may include control circuitry that can exchange data and control commands with controller 214 or special hardware registers that can be set by controller 214. DC-DC converter 212 may operate automatically based on a default setting or operate under the control of controller 214 to perform more complex operations.

Because the voltage generated by thermoelectric generator 210 may be dependent on the temperature difference across the thermoelectric material, and the temperature difference can vary significantly, the generated voltage may also vary significantly. Controller 214 may be configured to control both thermoelectric generator 210 and DC-DC converter 212. For example, controller 214 may control DC-DC converter 212 to adjust significant voltage changes on output/input voltage terminal 220 of thermoelectric generator 210 to maintain the voltage applied to electric bus 216 at a constant desirable level. In certain embodiments, the temperature difference may be maintained by the system of work machine 100. DC-DC converter 2112 may be controlled by controller 214 to extract maximum electrical power from the thermal energy in the exhaust stream while operating the cooling system with a normal operational range. Electric bus 216 may operate at any desired voltage level and may provide electricity for various systems (not shown) within or associated with work machine 100. In certain embodiments, electric bus 216 may operate at a voltage level such as 14.4V, 30V, 300V, or any other desired level.

In certain embodiments, thermoelectric generator 210 may include on-board control circuitry capable of exchanging data and control commands with controller 214. Alternatively, thermoelectric generator 210 may include control registers or other mechanisms that can be directly controlled by controller 214. In addition to voltage control, controller 214 may also control other operations of thermoelectric generator 210 and DC-DC converter 212. For example, controller 214 may perform certain operations to reduce or minimize thermoelectric generator 210's impact on the cooling system. Because thermoelectric generator 210 may require a significant amount of cooling to maintain a desired temperature differential across the thermoelectric materials, a significant load, at times, may be placed on the cooling system of work machine 100. In certain situations, the cooling load of thermoelectric generator 210 combined with cooling loads from engine 202 and other systems may surpass a design limit of the cooling system on work machine 100, which may result in damage to engine 202 or other systems. Rather than operating thermoelectric generator 210 at all times, controller 214 may monitor operations of engine 202 and the cooling system and may limit the operation of thermoelectric generator 210 to periods of time when sufficient cooling resources are available. Controller 214 may make such a determination based on the cooling capacity of the cooling system, the cooling requirements of engine 202 and other systems, and the cooling requirements of thermoelectric generator 210, etc.

In one embodiment, controller 214 may also control the operations of thermoelectric generator 210 to enhance cooling capacity of work machine 100. For instance, controller 214 may selectively control the magnitude and polarity of the voltage level applied to the thermoelectric materials to effectively create a heat sink such that thermoelectric generator 210 may take heat away from cooling line 218 and transfer the heat to the exhaust stream in exhaust line 206. Controller 214 may operate thermoelectric generator 210 in this manner to help prevent overheating of the cooling system. Those skilled in the art will recognize that other operations of thermoelectric generator 210 may also be performed by controller 214.

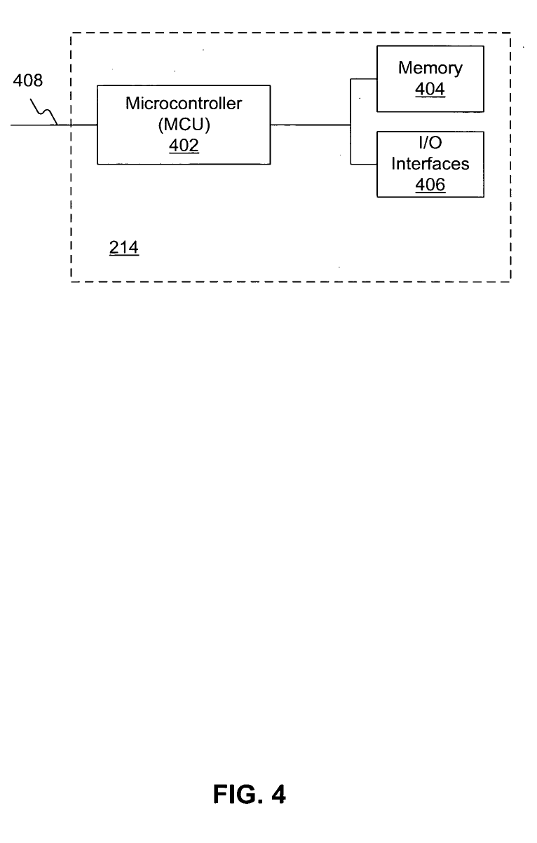

To perform these operations, controller 214 may be configured to execute certain software programs. FIG. 4 shows an exemplary functional block diagram of controller 214 consistent with this disclosed embodiment. As shown in FIG. 4, controller 214 may include a microcontroller unit (MCU) 402, a memory module 404, I/O interfaces 406, and a bus 408. Other components may also be included in controller 214. Additionally, controller 214 may coincide with an electronic control unit (ECU) (not shown) for work machine 100.

MCU 402 may be configured as a separate processor module dedicated to control thermoelectric generator 210 and DC-DC converter 212. Additionally or alternatively, MCU 402 may be configured as a shared processor module performing other functions unrelated to thermoelectric generator 210 and DC-DC converter 212. MCU 402 may be one or more microcontrollers with on-board memory, network ports (i.e., controller area network (CAN) ports), pulse width modulation (PWM) ports (not shown), and I/O ports (not shown). Further, MCU 402 may also be configured as a microprocessor supported by various memory modules and peripheral devices. In certain embodiments, MCU 402 may communicate with other controllers (not shown) via bus 408 under predetermined protocols, such as J1939. Other communication protocols and bus types, however, may also be used.

Memory module 404 may be one or more memory devices including, but not limited to, a ROM, a flash memory, a dynamic RAM, and a static RAM. Memory module 404 may be configured to store information used by MCU 402. Further, memory module 404 may be external or internal to MCU 402. I/O interfaces 406 may be one or more input/output interface devices receiving data (e.g., control signals) from MCU 402 and sending data (e.g., interrupt signals) to MCU 402. I/O interfaces 406 may also be connected to various sensors or other components (not shown) to monitor operations of engine 202, the exhaust system, the cooling system, thermoelectric generator 210, and/or DC-DC converter 212.

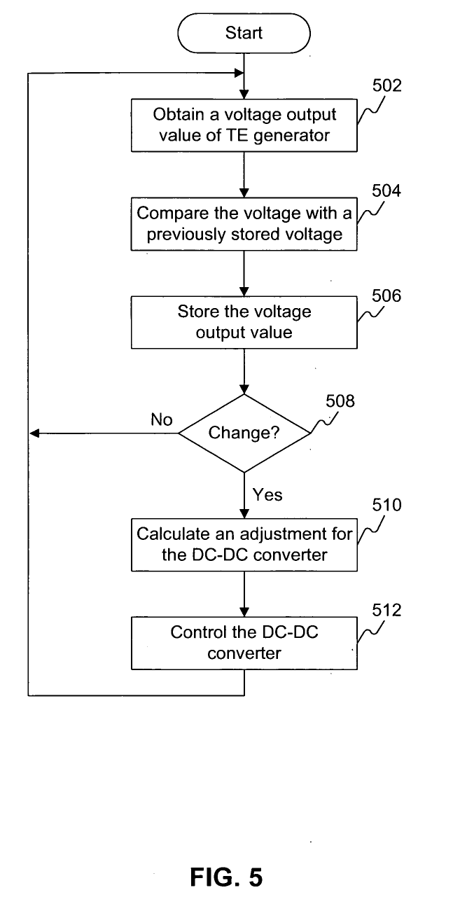

In operation, controller 214 may execute software programs stored in memory module 404 to perform a variety of operation processes. For example, controller 214 may perform an automatic voltage conversion process to allow DC-DC converter 212 to provide an output voltage at a constant desirable level. As shown in FIG. 5, at the beginning of the automatic voltage conversion process, controller 214 obtains a voltage value on output/input voltage terminal 220 of thermoelectric generator 210 (step 502). Controller 214 may obtain the voltage value directly from thermoelectric generator 210 or by monitoring voltage sensors (not shown) configured to monitor output/input voltage terminal 220 of thermoelectric generator 210. Once controller 214 obtains the current voltage value (step 502), controller 214 may compare the current voltage value with a previously stored voltage value (step 504). The current voltage value may be stored and may replace the previously stored voltage value (step 506). According to the result of the comparison, controller 214 may further determine whether there is any voltage change on output/input voltage terminal 220 of thermoelectric generator 210 (step 508). If no voltage change has occurred on the voltage output, or alternatively, if the changed voltage level is within an operational range of DC-DC converter 212 (step 508; no), the automatic voltage conversion process returns to step 502. The operational range may be predetermined and may correspond to a range of input voltage values for which DC-DC converter 212 may supply a constant desired output voltage level.

On the other hand, if the output voltage changes, or alternatively, the changed voltage level is out of the operational range of DC-DC converter (step 508; yes), controller 214 may then calculate an adjustment for DC-DC converter 212 such that the output voltage from DC-DC converter 212 can be kept at a constant desirable level (step 510). Further, controller 214 may control DC-DC converter 212 based on the adjustment calculated (step 512). To control DC-DC converter 212, controller 214 may issue control commands or send messages to DC-DC converter 212. Alternatively, controller 214 may also directly change hardware registers on DC-DC converter 212 via I/O interfaces 406 to adjust the voltage change. Under the control of controller 214, DC-DC converter 212 can regulate and/or convert the voltage supplied by thermoelectric generator 210 to an output voltage at a constant voltage level compatible with bus 216, which may operate at any desired voltage level (e.g., 14.4V, 30V, 300V, etc.).

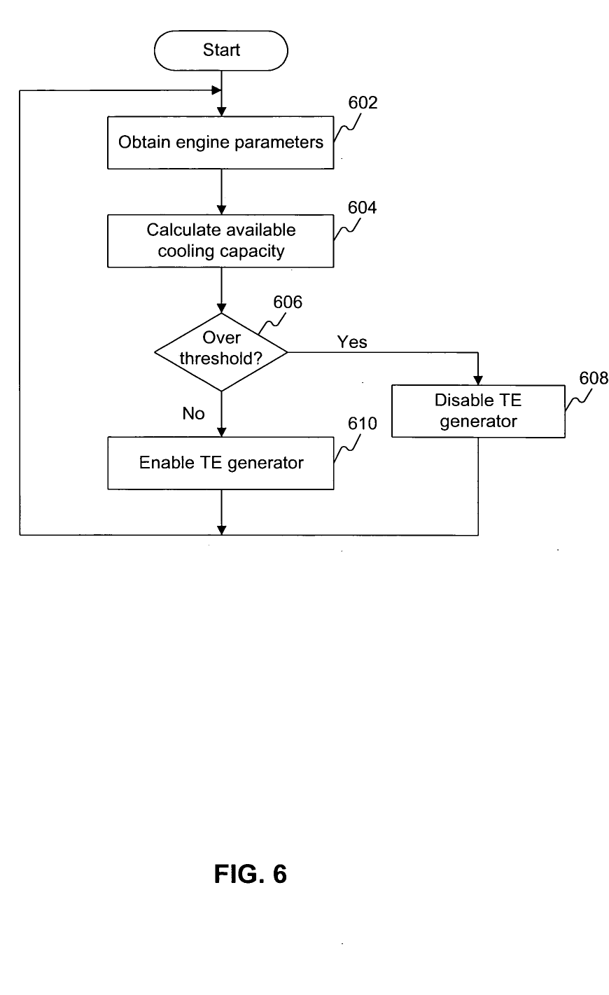

Controller 214 may also perform a control process to selectively operate thermoelectric generator 210, as shown in FIG. 6. By receiving engine parameters from engine control systems via internal bus (e.g., bus 408), or by monitoring various engine sensors (not shown), controller 214 may obtain engine parameters of engine 202 (step 602). The engine parameters may include engine speed, engine torque, engine temperature, coolant temperature, engine exhaust temperature, or any other type of engine parameter related to engine operations and/or cooling system operations. Controller 214 may calculate an available cooling capacity of work machine 100 (step 604). Additionally or alternatively, controller 214 may also receive machine parameters, such as machine ground speed and ambient temperature, via internal bus (e.g., bus 408). These machine parameters may also be used to determine the available cooling capacity. In one embodiment, the available cooling capacity may be associated with engine torque. For example, if engine 202 is outputting a small torque, the available cooling capacity may be large. Conversely, the available cooling capacity may be small if engine 202 is outputting a large torque. In another embodiment, the available cooling capacity may also be associated with engine speed. For example, the available cooling capacity may be large if engine 202 reaches a cruising speed and needs less cooling. In certain other embodiments, the available cooling capacity may be determined based on a combination of various engine parameters, information from other components (not shown) on work machine 100, and total cooling capacity of work machine 100.

Based on the determined cooling capacity (step 604), controller 214 may estimate a cooling requirement of thermoelectric generator 210. In certain embodiments, the cooling requirement of thermoelectric generator 210 may be estimated based on exhaust temperature, total amount of electricity to be generated, and/or the characteristics of the thermoelectric materials in thermoelectric generator 210. Controller 214 may further compare the available cooling capacity of work machine 100 and the cooling requirement of thermoelectric generator 210, and determine whether the cooling requirement exceeds the available cooling capacity or a determined threshold within the available cooling capacity set to keep a safe margin (step 606). If the cooling requirement does not exceed the available cooling capacity or the cooling capacity threshold (step 606; no), controller 214 may enable thermoelectric generator 210 or continue to operate thermoelectric generator 210 if thermoelectric generator 210 is already enabled (step 610). Alternatively, controller 214 may adjust the operation of already enabled thermoelectric generator 210 as not to exceed the available cooling capacity or the cooling capacity threshold.

On the other hand, if controller 214 determines that the cooling requirement of thermoelectric generator 210 exceeds the available cooling capacity or the cooling capacity threshold (step 606; yes), controller 214 may disable thermoelectric generator 210 (step 608). For example, controller 214 may turn off thermoelectric generator 210 or may keep thermoelectric generator turned off if thermoelectric generator 210 has not been turned on. Alternatively, controller 214 may also adjust the operation of thermoelectric generator 210 as not to exceed the available cooling capacity or the cooling capacity threshold.

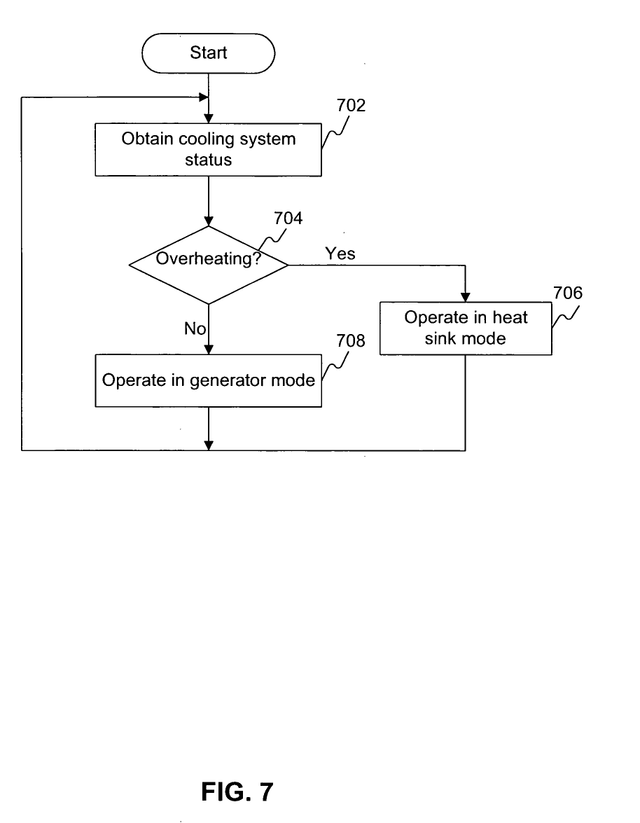

Controller 214 may also control thermoelectric generator 210 to enhance cooling capacity of work machine 100. FIG. 7 illustrates an exemplary dual-mode operational process performed by controller 214. As shown in FIG. 7, at the beginning of the dual-mode operational process, controller 214 may obtain status information of cooling system, such as coolant temperature and cooling line temperature (step 702). Controller 214 may then determine whether an overheat condition exists (step 704). If the cooling system is not overheating (step 704; no), controller 214 may continue to operate thermoelectric generator 210 in generator mode (step 708). As explained above, when operating in generator mode, heat (i.e., thermal energy) is transferred from the exhaust to the cooling system. A portion of this thermal energy may be converted to electricity by being converted to a desirable level voltage. The voltage may then be applied to electric bus 216.

If, however, controller 214 determines that the cooling system is overheating or that a danger of overheating exists (step 704; yes), controller 214 may then operate thermoelectric generator 210 in heat sink mode (step 706). To operate thermoelectric generator 210 in heat sink mode, controller 214 may control thermoelectric generator 210 such that thermoelectric generator 210 no longer accepts exhaust heat. Alternatively, controller 214 may minimize the net flow of thermal energy from exhaust stream to the cooling system. Controller 214 may further control DC-DC converter 212 and thermoelectric generator 210 to apply a voltage, from electric bus 216, to thermoelectric generator 210 via output/input voltage terminal 220. The applied voltage may cause heat to flow from coolant in cooling line 218 to the exhaust stream in exhaust line 206. As a result, thermoelectric generator 210 may provide supplemental cooling to the cooling system of work machine 100. To supply the voltage, controller 214 may further control starter generator 208 or other source of energy, such as batteries, to provide electrical power to electrical bus 216. This process may be performed for any condition where it may be desirable to transfer heat from a cooling system to an exhaust system.

### INDUSTRIAL APPLICABILITY

The disclosed methods and systems may be incorporated in any vehicles or work machines where it would be desirable to recover waste heat energy and contribute to the increased overall efficiency of a waste heat generating system. By recovering a portion of the waste heat energy, vehicles or work machines may become more efficient and use less fuel.

The disclosed methods and systems also provide a stable and constant power supply generated from waste heat energy. Because energy levels generated from waste heat can vary significantly, the disclosed methods and systems can automatically and effectively convert a variable output voltage from a thermoelectric generator to a constant voltage at a desired level. This smart converter may also be used to provide stable and constant power from other unstable power sources other than thermoelectric generators.

Further, the disclosed methods and systems may also be used where enhanced and controlled cooling requirements exist. Certain advantages such as operating in either a generator mode or a heat sink mode may be recognized and realized on many other systems made by engine manufacturers and on-highway truck makers.

Those skilled in the art will recognize that the processes described above are exemplary only and not intended to be limiting. Other processes may be created, steps in the described processes may be removed or modified, the order of these steps may be changed, and/or other operation steps may be added without departing from the principle and scope of disclosed embodiments.

What is claimed is:

1. A method for use in a thermoelectric generator control system having a thermoelectric generator, a DC-DC converter, and a controller, comprising:
monitoring a voltage output of the thermoelectric generator;
determining a voltage change on the voltage output;
calculating an adjustment for the DC-DC converter in response to the voltage change on the voltage output such that an output voltage from the DC-DC converter remains at a predetermined voltage level; and
applying the adjustment to the DC-DC converter.

2. The method according to claim 1, wherein the thermoelectric generator includes a low dimensional thermoelectric material.

3. The method according to claim 2, wherein the low dimensional thermoelectric material is a zero-dimensional quantum dots thermoelectric material.

4. The method according to claim 2, wherein the low dimensional thermoelectric material is a one-dimensional nano wires thermoelectric material.

5. The method according to claim 2, wherein the low dimensional thermoelectric material is a two-dimensional quantum well thermoelectric material.

6. The method according to claim 2, wherein the low dimensional thermoelectric material is a superlattice structured thermoelectric material.

7. The method according to claim 1, wherein the thermoelectric generator includes a thermoelectric material with a figure of merit ZT between 0.5 and 10.

8. A method for use in a thermoelectric generator control system having a thermoelectric generator and a controller for controlling the thermoelectric generator, comprising:
obtaining operational parameters from an engine associated with a cooling system;
calculating an available cooling capacity of the cooling system;
estimating a cooling requirement for the thermoelectric generator; and
determining whether the cooling requirement exceeds the available cooling capacity.

9. The method according to claim 8, further including:
disabling the thermoelectric generator if it is determined that the cooling requirement exceeds the available cooling capacity; and
enabling the thermoelectric generator if it is determined that the cooling requirement does not exceed the available cooling capacity.

10. The method according to claim 8, wherein the operational parameters include one or more of engine speed, engine torque, and engine temperature.

11. The method according to claim 10, wherein calculating includes:
calculating the available cooling capacity based on the engine torque.

12. A method for use in a thermoelectric generator control system having a controller and a thermoelectric generator associated with a cooling system for controlling an operation mode of the thermoelectric generator, comprising:
obtaining status information of the cooling system and an engine associated with the cooling system;
determining an overheat condition of the cooling system; and
operating the thermoelectric generator in a heat sink mode such that heat is transferred from the cooling system to the exhaust stream.

13. The method according to claim 12, wherein determining includes:
determining the overheat condition of the cooling system based on engine temperature.

14. The method according to claim 12, wherein operating the thermoelectric generator in heat sink mode includes:
applying a predetermined voltage to the thermoelectric generator; and
causing at least some heat to flow from the cooling system to the exhaust system.

15. A thermoelectric generator system for use on a work machine having an engine, comprising:
a thermoelectric generator selectively accepting an exhaust stream from the engine to generate a voltage on a generator voltage output;
a DC-DC converter having a voltage input coupled with the generator voltage output of the thermoelectric generator to convert the voltage to a predetermined level on a converter voltage output; and
a controller coupled to both the DC-DC converter and the thermoelectric generator and configured to maintain the predetermined level on the converter voltage output.

16. The system according to claim 15, wherein the thermoelectric generator includes a low dimensional thermoelectric material.

17. The system according to claim 15, wherein the thermoelectric generator includes zero-dimensional quantum dots of lead-tin-selenium-telluride.

18. The system according to claim 15, further including:
an electric bus operatively coupled with the converter voltage output to accept a converted voltage from the DC-DC converter.

19. The system according to claim 15, wherein the controller includes:
a memory module;
a microcontroller unit for executing software programs stored in the memory module; and
at least one I/O interface.

20. A control system of a work machine for use in a thermoelectric generator system having a thermoelectric generator and a DC-DC converter, comprising:
a microcontroller unit configured to perform operations to:
maintain a constant output voltage level on a voltage output of the DC-DC converter;
selectively control an operation period of the thermoelectric generator based on an available cooling capacity of the work machine; and
selectively control an operation mode of the thermoelectric generator based on conditions of a cooling system of the work machine to enhance a total cooling capacity of the work machine.

21. The control system according to claim 20, further including:
at least one I/O interface configured to monitor one or more parameters associated with the thermoelectric generator, the DC-DC converter, and the cooling system.

22. A work machine, comprising:
an engine providing power to the work machine and producing an exhaust stream including waste heat;
a thermoelectric generator having a high efficiency thermoelectric material to generate an output voltage using the exhaust stream;
an exhaust system carrying the exhaust stream to the thermoelectric generator; and
a DC-DC converter to convert the output voltage to a converted output voltage at a predetermined level.

23. The work machine according to claim 22, wherein the high efficiency thermoelectric material is zero-dimensional quantum dots of lead-tin-selenium-telluride.

24. The work machine according to claim 22, further including:
a controller coupled to the thermoelectric generator and the DC-DC converter to maintain the converted output voltage at the constant predetermined level.

25. The work machine according to claim 24, further including:
a cooling system providing cooling capacity for both the engine and the thermoelectric generator.

26. The work machine according to claim 25, further including:
an electric bus coupled with the DC-DC converter to accept the converted output voltage from the DC-DC converter.
